(19) United States
(12) Patent Application Publication
(10) Pub. No.: US 2026/0150686 A1
(43) Pub. Date: May 28, 2026

(54) INTEGRATED CIRCUIT PACKAGES AND METHODS OF FORMING THE SAME

(71) Applicant: Taiwan Semiconductor Manufacturing Co., Ltd., Hsinchu (TW)

(72) Inventors: Li-Hsien Huang, Zhubei City (TW); Kuan-Yu Chen, Hsinchu (TW); Chin-Hsien Chen, New Taipei City (TW); Yung Lin Tan, Taichung City (TW); Hsi-Kuei Cheng, Zhubei City (TW)

(21) Appl. No.: 18/961,819

(22) Filed: Nov. 27, 2024

(51) Int. Cl. H01L 23/00; H01L 21/48; H01L 21/56; H01L 21/683; H01L 21/768; H01L 23/31; H01L 23/498; H01L 23/538; H01L 25/18; H10B 80/00

(52) U.S. Cl. CPC H10W 42/121; H10W 20/081; H10W 70/05; H10W 70/093; H10W 70/095; H10W 70/65; H10W 74/016; H10W 74/117; H10W 90/401; H10B 80/00; H10P 72/74; H10W 72/29; H10W 74/15; H10W 90/00; H10W 90/724; H10W 90/734; H10W 90/792

(57) ABSTRACT

A method includes forming an interconnection die that comprises through vias extending partially through a semiconductor substrate, an interconnect structure over the semiconductor substrate, and die connectors over the interconnect structure. A protection layer is applied over the die connectors and then patterned to form protective coverings around the die connectors. An encapsulant is formed over and around the interconnection die and the protective coverings. A first planarization process is performed to level the encapsulant, the protective coverings, and the die connectors. A first redistribution structure is formed over and electrically connected to the die connectors.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2A-2B are cross-sectional views of die stacks.

FIGS. 3A-5C are views of intermediate stages in the fabrication of an interconnection die, in accordance with various embodiments.

FIGS. 6-14 are views of intermediate stages in the fabrication of an integrated circuit package, in accordance with various embodiments.

FIGS. 15A-15C are cross-sectional views of interconnection dies, in accordance with various embodiments.

FIGS. 16A and 16B are cross-sectional views of interconnection dies, in accordance with various embodiments.

FIGS. 17A-17C are cross-sectional views of interconnection dies, in accordance with various embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, an interposer of an integrated circuit package includes a molding compound between two redistribution structures. Interconnection dies and through vias are disposed in the molding compound, and thus are embedded in the interposer. The interconnection dies are formed are fabricated at wafer level and may include die connectors that will provide electrical connection to the redistribution structures. A protective layer is formed over and around the die connectors and patterned into distinct protective coverings for individual or groupings of the die connectors. As a result, the protective coverings provide protective benefits to the die connectors while reducing warpage of the interconnection die and thereby improving the quality of the integrated circuit package during subsequent steps. In particular, the interconnection dies may be singulated from the wafer and attached to a carrier substrate. A molding compound is formed over and around the interconnection dies, and a first redistribution structure is formed over the interconnection dies. Integrated circuit dies are then attached to the first redistribution structure, and the carrier substrate is removed in order to form a second redistribution structure on an opposing side of the interconnection dies.

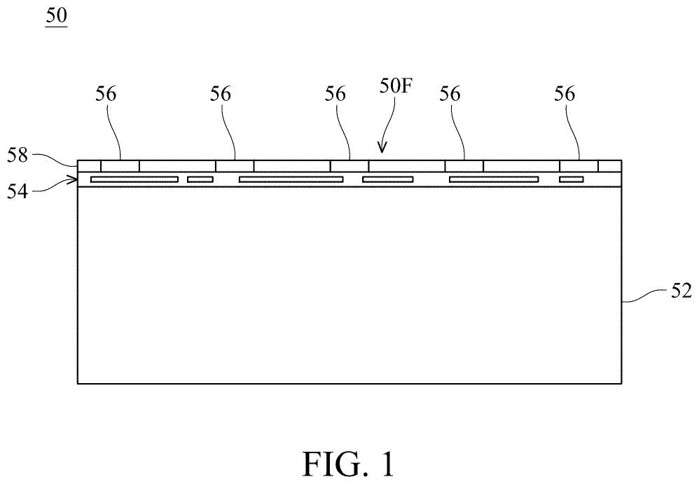

FIG. 1 is a cross-sectional view of an integrated circuit die 50. Multiple integrated circuit dies 50 will be packaged in subsequent processing to form integrated circuit packages. Each integrated circuit die 50 may be a logic die (e.g., central processing unit (CPU), graphics processing unit (GPU), system-on-a-chip (SoC) die, microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit die 50 may be formed in a wafer, which may include different die regions that are singulated in subsequent steps to form a plurality of integrated circuit dies 50. The integrated circuit die 50 includes a semiconductor substrate 52, an interconnect structure 54, die connectors 56, and a dielectric layer 58.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) are at the active surface of the semiconductor substrate 52. The devices may be active devices (e.g., transistors, diodes, etc.), capacitors, resistors, etc. The inactive surface may be free from devices.

The interconnect structure 54 is over the active surface of the semiconductor substrate 52, and is used to electrically connect the devices of the semiconductor substrate 52 together to form an integrated circuit. The interconnect structure 54 may include one or more dielectric layer(s) and respective metallization layer(s) in the dielectric layer(s). Acceptable dielectric materials for the dielectric layers include oxides such as silicon oxide or aluminum oxide, nitrides such as silicon nitride, combinations thereof such as silicon oxynitride, or the like. Other dielectric materials may also be used, such as a polymer, such as polybenzoxazole (PBO), polyimide, a benzocyclobuten (BCB) based polymer, or the like. The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

Die connectors 56 are at the front-side 50F of the integrated circuit die 50. The die connectors 56 may be conductive pillars, pads, or the like, to which external connections are made. The die connectors 56 are in and/or on the interconnect structure 54. For example, the die connectors 56 may be part of an upper metallization layer of the interconnect structure 54. The die connectors 56 may be formed of a metal, such as copper, aluminum, or the like, and may be formed by, for example, plating, or the like.

Optionally, solder regions (not separately illustrated) may be disposed on the die connectors 56 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 56. Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged. After testing, the solder regions may be removed.

A dielectric layer 58 is at the front-side 50F of the integrated circuit die 50. The dielectric layer 58 is in and/or on the interconnect structure 54. For example, the dielectric layer 58 may be an upper dielectric layer of the interconnect structure 54. The dielectric layer 58 laterally encapsulates the die connectors 56. The dielectric layer 58 may be an oxide, a nitride, a polymer, the like, or a combination thereof, which may be formed, for example, by spin coating, lamination, chemical vapor deposition (CVD), or the like. Front-side surfaces of the die connectors 56 and the dielectric layer 58 may be substantially coplanar (within process variations) at the front-side 50F of the integrated circuit die 50.

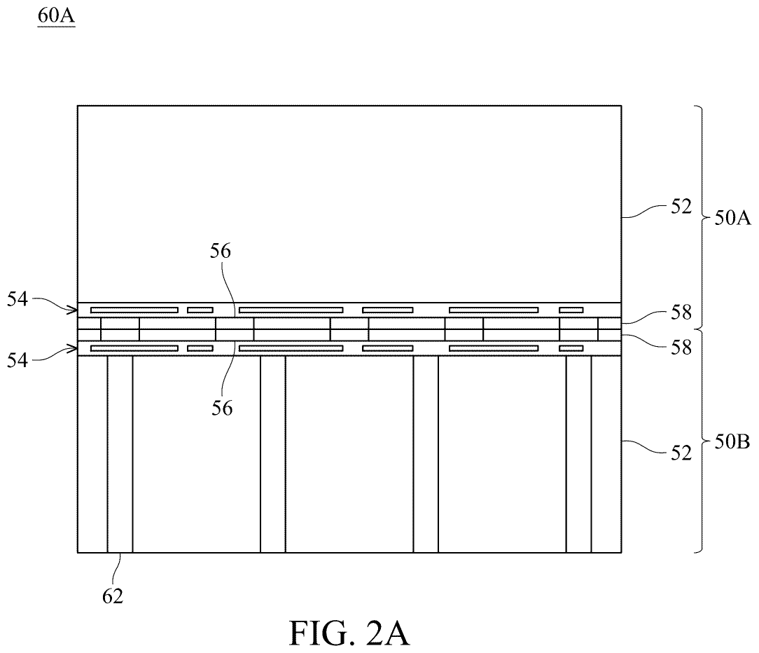

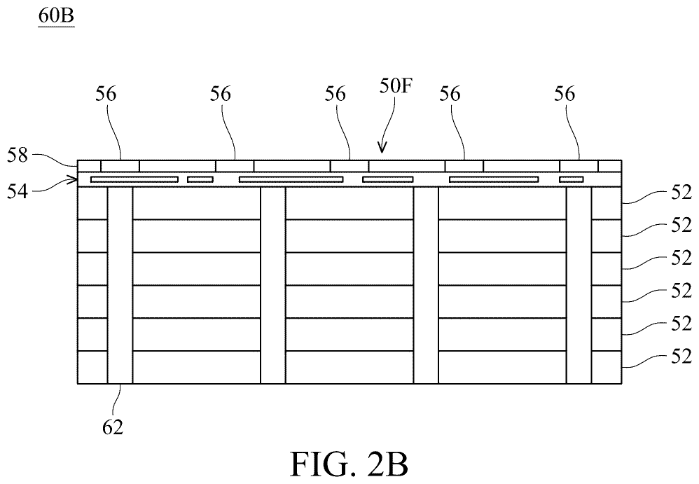

FIGS. 2A-2B are cross-sectional views of die stacks 60A, 60B, respectively. The die stacks 60A, 60B may each have a single function (e.g., a logic device, memory die, etc.), or may have multiple functions. In some embodiments, the die stack 60A is a logic device such as a system-on-integrated-chip (SoIC) device and the die stack 60B is a memory device such as high bandwidth memory (HBM) device.

As shown in FIG. 2A, the die stack 60A includes two bonded integrated circuit dies 50 (e.g., a first integrated circuit die 50A and a second integrated circuit die 50B). In some embodiments, the first integrated circuit die 50A is a logic die, and the second integrated circuit die 50B is an interface die. An interface die bridges a logic die to memory dies, and translates commands between the logic die and the memory dies. In some embodiments, the first integrated circuit die 50A and the second integrated circuit die 50B are bonded such that the active surfaces are facing each other (e.g., are “face-to-face” bonded). Conductive vias 62 may be formed through one of the integrated circuit dies 50 so that external connections may be made to the die stack 60A. The conductive vias 62 may be through-substrate vias (TSVs), such as through-silicon vias or the like. In the illustrated embodiment, the conductive vias 62 are formed in the second integrated circuit die 50B (e.g., the interface die). The conductive vias 62 extend through the semiconductor substrate 52 of the respective integrated circuit die 50, to be physically and electrically connected to the metallization layer(s) of the interconnect structure 54.

As shown in FIG. 2B, the die stack 60B is a stacked device that includes multiple semiconductor substrates 52. For example, the die stack 60B may be a memory device that includes multiple memory dies such as a hybrid memory cube (HMC) device, a high bandwidth memory (HBM) device, or the like. Each semiconductor substrate 52 may (or may not) have a separate interconnect structure 54. The semiconductor substrates 52 are connected by conductive vias 62, such as TSVs.

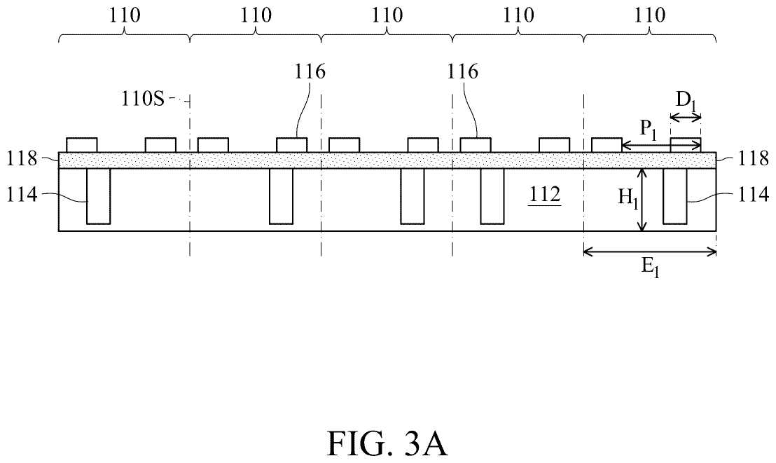

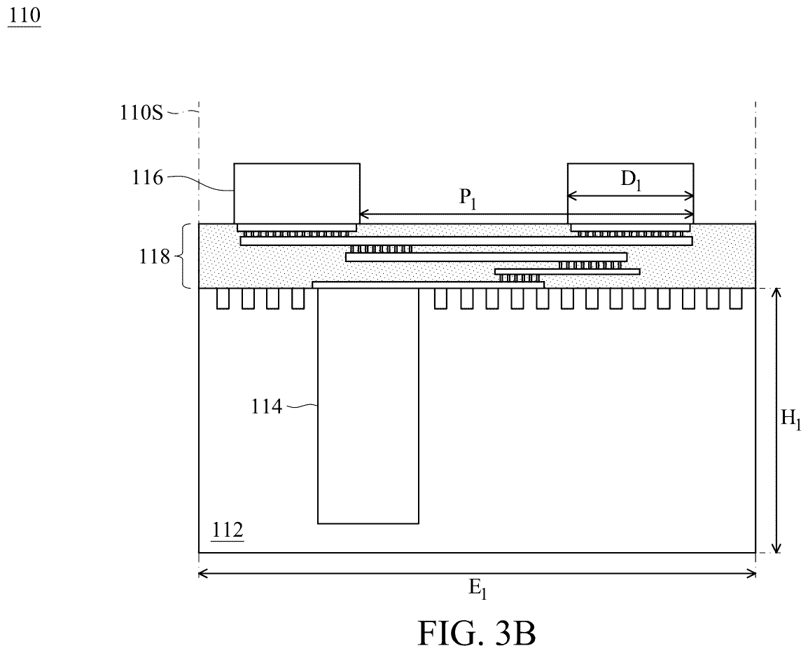

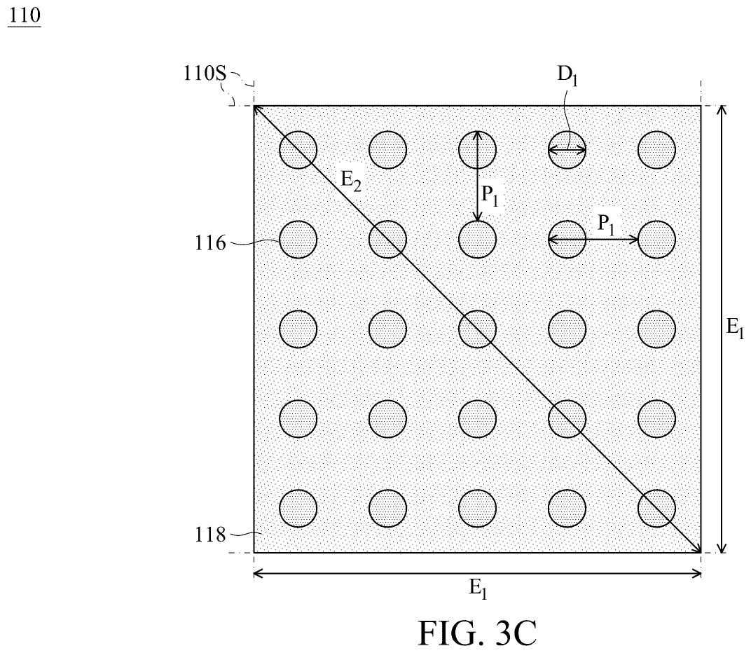

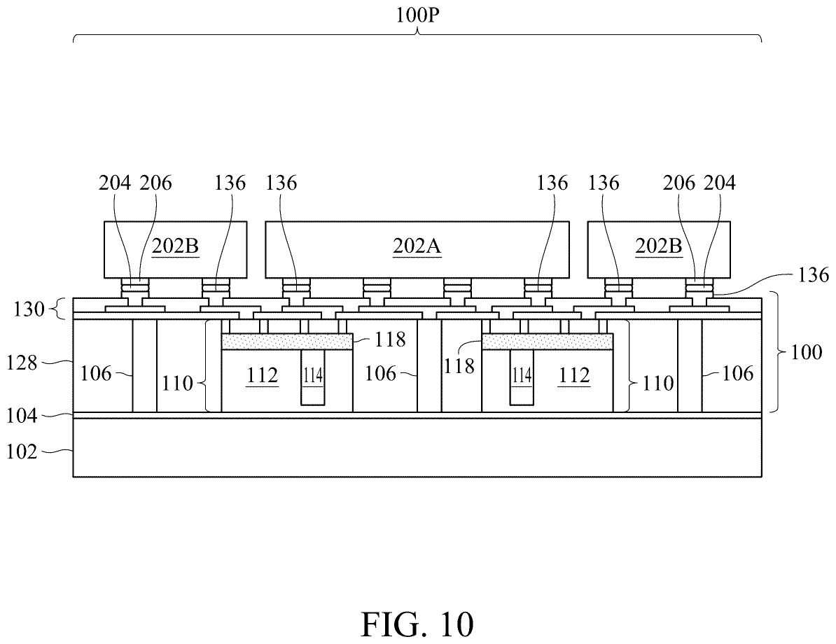

FIGS. 3-12 are views of intermediate stages in the manufacturing of an integrated circuit package 200 (see FIGS. 10-12), in accordance with some embodiments. FIGS. 3A-5B are views of intermediate stages in the manufacturing of interconnection dies 110. A package region 100P is illustrated, and an integrated circuit package 200 is formed in the package region 100P. Although a single package region 100P is illustrated, it should be appreciated that multiple package regions 100P may be formed. An interposer wafer 100 is formed. The interposer wafer 100 includes an interposer 240 in the package region 100P. Integrated circuit devices 202 are attached to the interposer 240. The interposer 240 may include interconnection dies 110 for interconnecting (e.g., electrically coupling) the integrated circuit devices 202 in the package region 100P. In addition, a package substrate 220 may be attached to the interposer 240. The package region 100P is singulated to form the integrated circuit package 200, which includes the package substrate 220 and a singulated portion of the interposer wafer 100 (e.g., the interposer 240). In an embodiment, the integrated circuit package 200 is a chip-on-wafer-on-substrate (CoWoS®) package, such as a CoWoS-L package, although it should be appreciated that embodiments may be applied to other three-dimensional integrated circuit (3DIC) packages.

In FIGS. 3A-3C, interconnection dies 110 are formed, in accordance with various embodiments. FIG. 3A illustrates a cross-sectional side view of the interconnection dies 110 at the wafer level. FIG. 3B illustrates a close-up cross-sectional side view of an interconnection die 110. FIG. 3C illustrates an exemplary plan view (e.g., top-down view) of a region of an interconnection die 110.

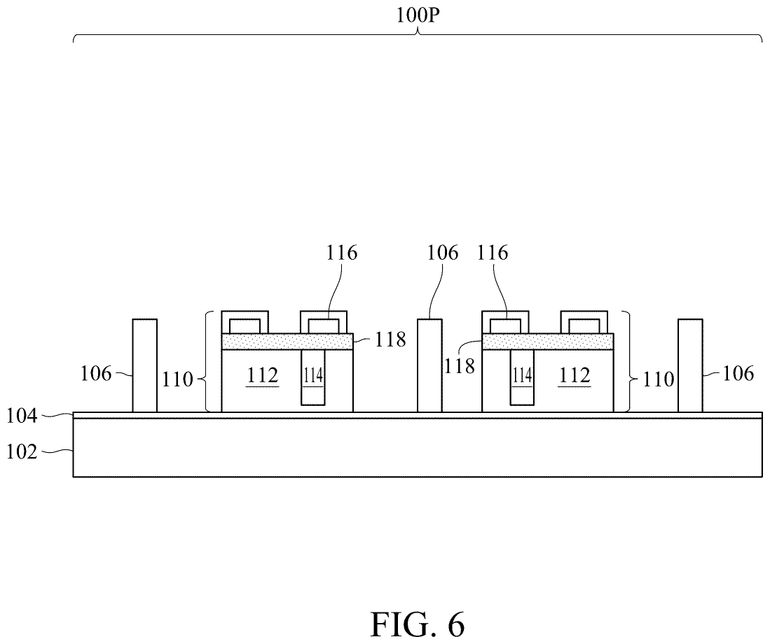

For example, the interconnection dies 110 will subsequently be singulated and incorporated into the interposer 240 as well as the integrated circuit package 200 (see FIG. 6). Each interconnection die 110 may be a local silicon interconnect (LSI), a large scale integration package, an interposer die, or the like. The interconnection dies 110 may be bridge dies.

Each interconnection die 110 includes a substrate 112, with conductive features formed in and/or on the substrate 112. The substrates 112 may include a semiconductor substrate, one or more dielectric layer(s), or the like. Additionally, each interconnection die 110 may include through-substrate vias (TSVs) 114 that extend into or through the substrate 112, and may be coupled to the conductive features of the interconnection die 110. In the illustrated embodiment, the substrates 112 initially cover the TSVs 114 at the back-sides of the interconnection dies 110. In another embodiment, the TSVs 114 are exposed at the back-sides of the interconnection dies 110. The interconnection die 110 also includes die connectors 116 disposed at the front-side of the interconnection die 110. Some of the die connectors 116 may be electrically coupled to the back-side of the interconnection die 110 by the TSVs 114. The TSVs 114 may be small, such as smaller than the through vias 106.

In some embodiments, the interconnection dies 110 may include die bridges 118. The die bridges 118 may be metallization layers formed in and/or on, e.g., the substrates 112, and work to interconnect integrated circuit devices (subsequently described) to one another. The die bridges 118 may include interconnects, redistribution lines, or the like. The die bridges 118 are located at the front-side of the interconnection dies 110. As such, the interconnection dies 110 can be used to directly connect and allow communication between integrated circuit devices. In such embodiments, the interconnection dies 110 may be placed in respective regions that are disposed between the subsequently attached integrated circuit devices, so that each interconnection die 110 is overlapped by multiple overlying integrated circuit devices. In some embodiments, the interconnection dies 110 may further include passive devices and/or active devices. In some embodiments, the interconnection dies 110 are substantially free of active devices and passive devices. The interconnection dies 110 may be placed over the carrier substrate 102 such that the die bridges 118 face away from the carrier substrate 102 (e.g., towards the subsequently attached integrated circuit devices).

In some embodiments, the substrate 112 of the interconnection die 110 may have a height H₁ ranging from 40 μm to 160 μm. In addition, edges of the interconnection die 110 may have same or different lengths E₁ (e.g., extending between scribe regions 110S) ranging from 5 mm to 32 mm, and a diagonal length E₂ may range from 7 mm to 46 mm. Further, the interconnection dies 110 may have total areas (e.g., a chip size as bounded by scribe regions 110S) ranging from 20 mm² to 270 mm². However, the interconnection dies 110 may have any suitable dimensions.

Moreover, the die connectors 116 may have lateral diameters D₁ ranging from 25 μm to 35 μm. The die connectors 116 may be arranged with a pitch P₁ greater than or equal to 35 μm. For example, the pitch P₁ may be at least 40% to 50% greater than the diameter D₁. Although illustrated as oval (e.g., circular), the die connectors 116 may include any suitable shapes, such as rectangular (e.g., square) with either rounded or sharp corners. The die connectors 116 may have a pattern density (see FIG. 3C) ranging from 2.5% to 40% of the total area of the interconnection die 110.

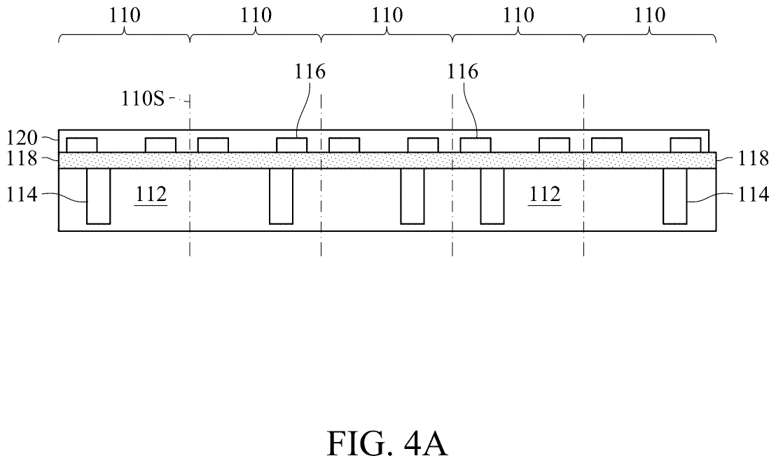

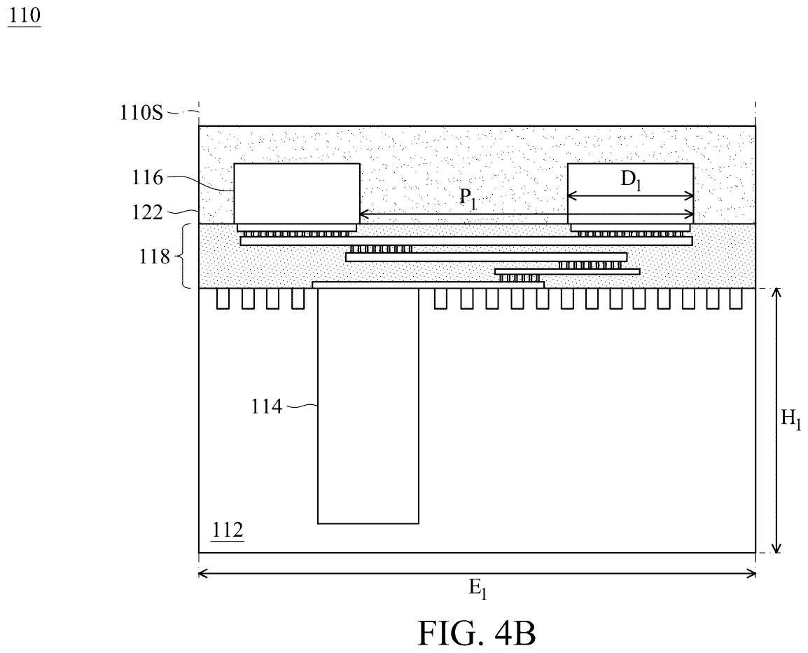

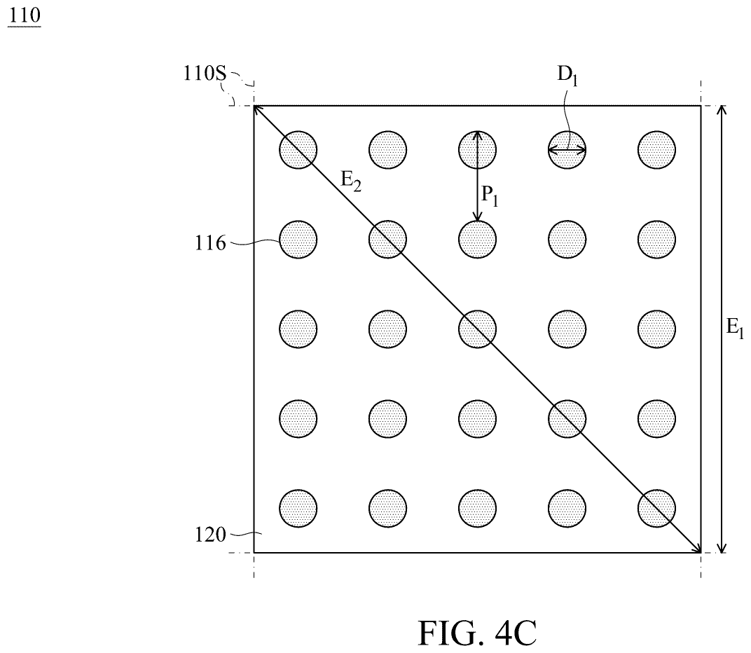

In FIGS. 4A-4C, a protection layer 120 is formed over and around the die connectors 116, in accordance with various embodiments. FIG. 4A illustrates a cross-sectional side view of the interconnection dies 110 at the wafer level. FIG. 4B illustrates a close-up cross-sectional side view of an interconnection die 110. FIG. 4C illustrates an exemplary plan view (e.g., top-down cross-sectional view) including the die connectors 116 of an interconnection die 110.

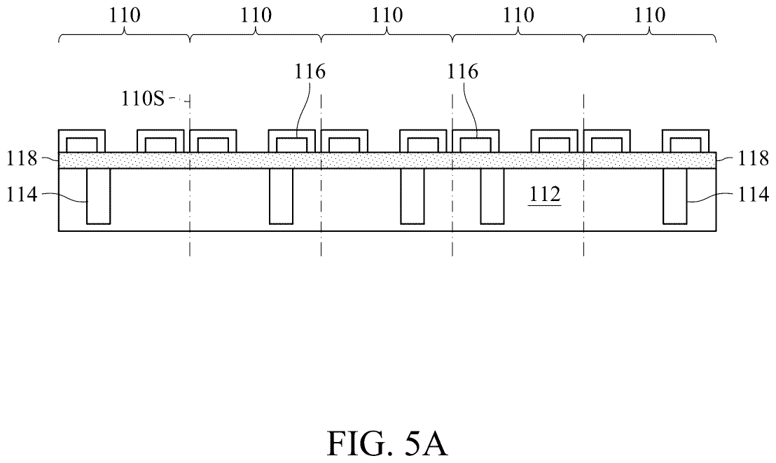

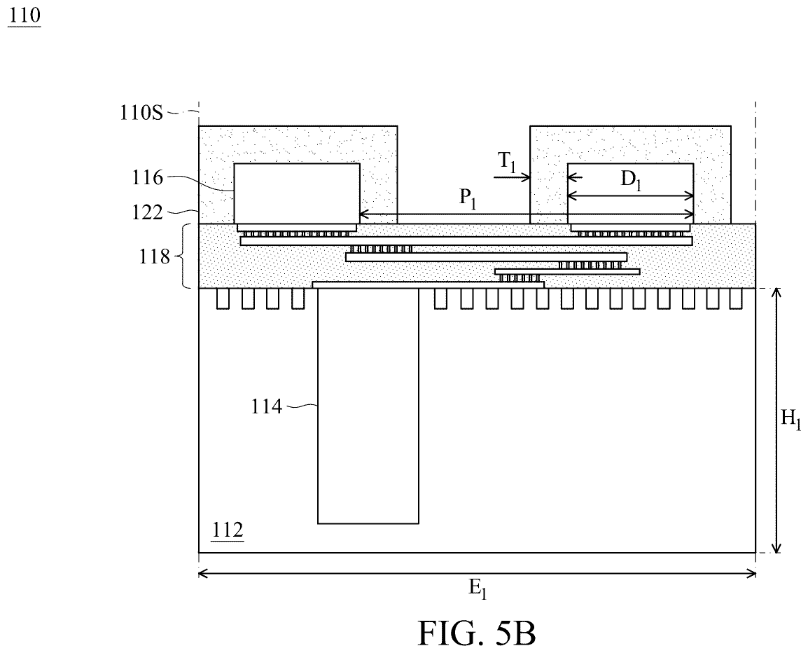

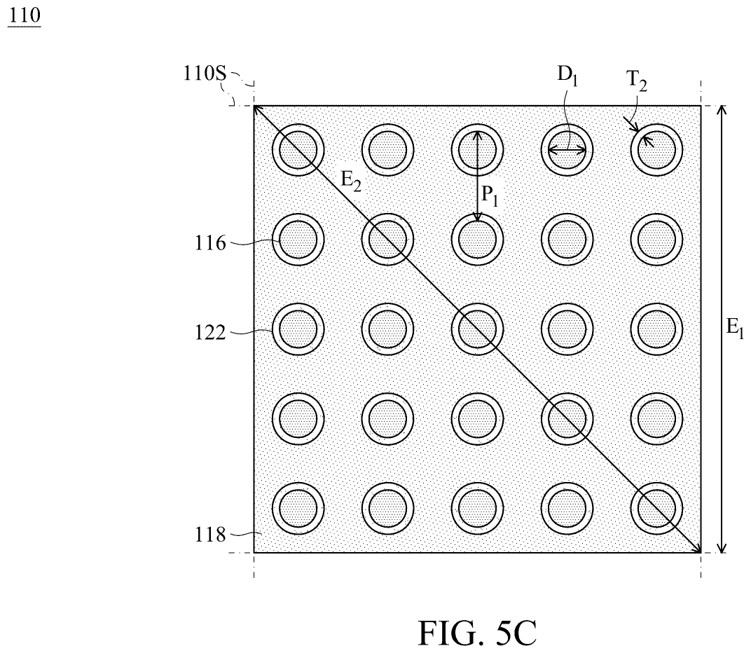

For example, the protection layer 120 is formed of a polymer, which may be a photosensitive material such as polyimide, PBO, a BCB-based polymer, or the like, that may be patterned using a lithography mask (see FIGS. 5A-5C). The protection layer 120 may be applied by spin coating, lamination, CVD, the like, or a combination thereof. In various embodiments, the protection layer 120 is a dielectric layer that can provide protection (e.g., oxidation and/or diffusion) and insulation to the underlying features (e.g., the die connectors 116). In addition, the protection layer 120 provides additional stability to the die connectors 116 and, generally, additional strength to the interconnection dies 110.

In FIGS. 5A-5C, the protection layer 120 is patterned to form protection coverings 122 around the die connectors 116, in accordance with various embodiments. In various embodiments, the protective coverings 122 are dielectric coverings which profiled to provide protection, insulation, and additional structural integrity to the underlying features. FIG. 5A illustrates a cross-sectional side view of the interconnection dies 110 at the wafer level. FIG. 5B illustrates a close-up cross-sectional side view of an interconnection die 110. FIG. 5C illustrates an exemplary plan view (e.g., top-down cross-sectional view) including the die connectors 116 of an interconnection die 110.

For example, the patterning may be performed using any acceptable process, such as by first exposing the protection layer 120 (e.g., comprising a photosensitive material) to light through a mask. The protection layer 120 may then be developed after the exposure by rinsing the structure with, for example, an aqueous base solution or any suitable developer. The remaining portions of the protection layer 120 may be cured to form the protective coverings 122. Note that the protective coverings 122 may be considered part of the interconnection dies 110.

In accordance with some embodiments, the curing process may cause the protective coverings 122 to shrink by up to 30%. This shrinkage may contribute to stress and warpage of the interconnection die 110. In particular, the shrinkage may form stress in the interconnection die 110 which causes warpage at this stage and/or at subsequent steps during fabrication of the integrated circuit package 200. However, converting the protection layer 120 to the smaller protective coverings 122 reduces many of the effects from shrinkage. As discussed in greater detail below, thicknesses and profile shapes of the protective coverings 122 may be selected to achieve this benefit while maintaining the advantages associated with protection, insulation, and structural support of the die connectors 116.

In some embodiments, the die connectors 116 and the protective coverings 122 have a one-to-one correspondence such that each protective covering 122 covers a distinct die connector 116. After patterning (e.g., curing), each of the protective coverings 122 may have a lateral thickness T₁ along and throughout a height of sidewalls of the die connectors 116 ranging from 10 μm to 30 μm. For example, the thickness T₁ may be between about 30% and about 100% of the diameter D₁ of the corresponding die connector 116 (e.g., the thickness T₁ may be lesser than or equal to the diameter D₁). In particular, the thicknesses T₁ being greater than 10 μm (or about 30% of the corresponding diameter D₁) ensures that the die connectors 116 are adequately protected, insulated, and reinforced. In addition, the thicknesses T₁ being less than 30 μm (or about 100% of the corresponding diameter D₁) reduces certain effects caused by thermal expansion mismatches between the protective coverings 122 and adjacent features. For example, utilizing less material of the protective coverings 122 ensures less stress in the interconnection die 110 which results in less warpage and thereby prevents other effects such as delamination during various steps of fabricating the integrated circuit package 200. Indeed, stress build-up and warpage may be prevented or reduced during the curing of the protective coverings 122.

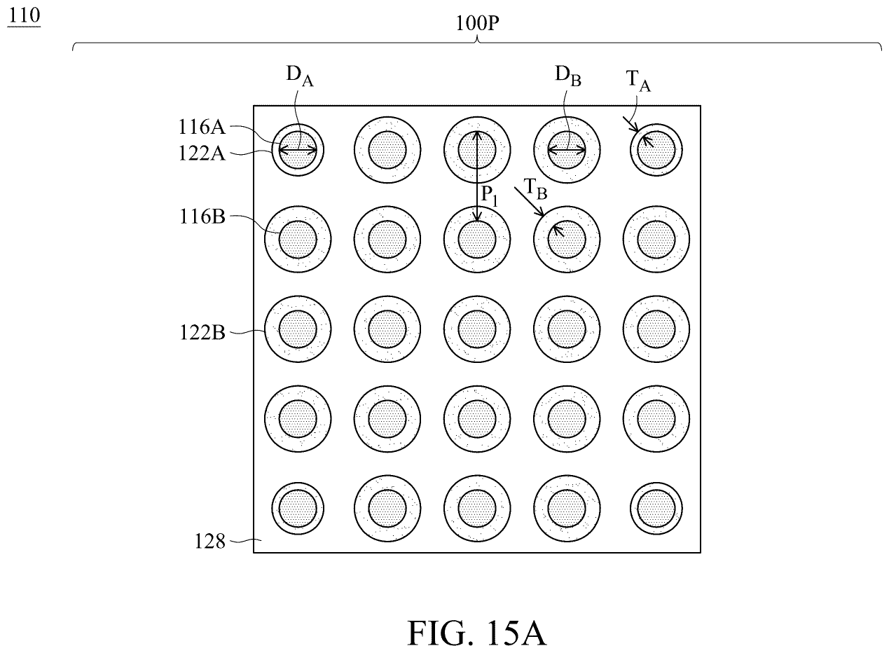

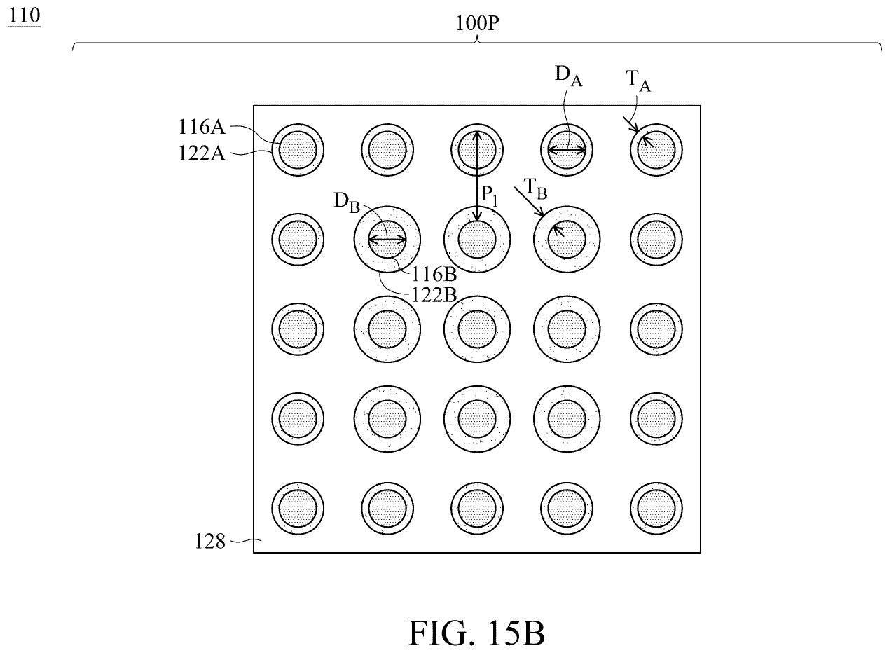

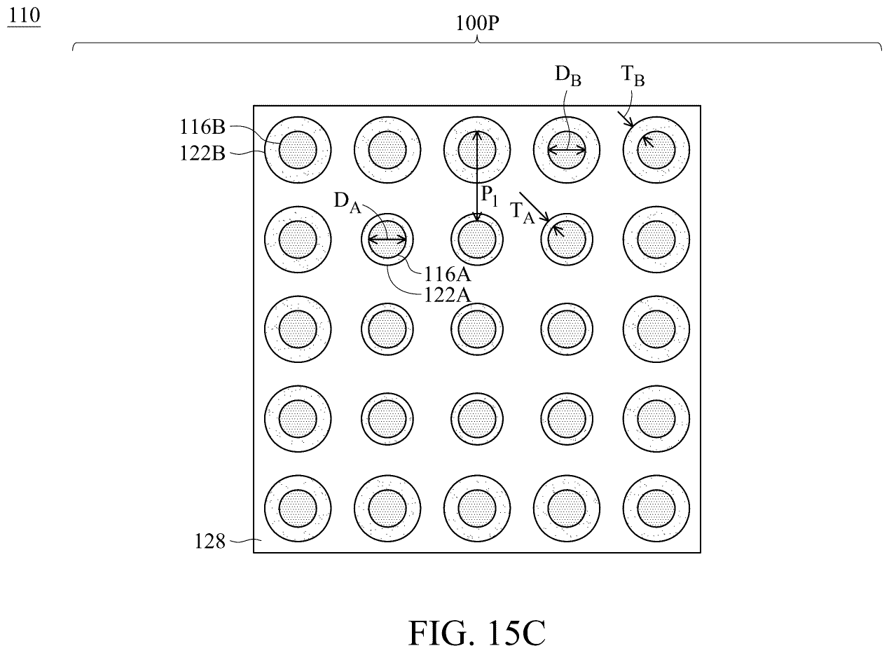

Furthermore, the dimensions and other parameters selected for the protective coverings 122 achieve analogous benefits during subsequent steps discussed in greater detail below. These features are described below in greater detail in connection with FIGS. 15A-17C.

In FIG. 6, through vias 106 are formed over a carrier substrate 102, and the interconnection dies 110 are attached to the carrier substrate 102, in accordance with various embodiments. The carrier substrate 102 may be a glass carrier substrate, a ceramic carrier substrate, or the like. The carrier substrate 102 may be a wafer, such that multiple packages can be formed on the carrier substrate 102 simultaneously. A release layer 104 may be formed on the carrier substrate 102 before forming and attaching the through vias 106 and the interconnection dies 110, respectively.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

The through vias 106 are formed over the release layer 104. Although the illustrated cross-section shows three through vias 106, it should be appreciated that any number of through vias 106 may be formed and that others of the through vias 106 are located in other cross-sections. As an example to form the through vias 106, a seed layer (not separately illustrated) is formed over the release layer 104. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as physical vapor deposition (PVD) or the like. A photoresist is then formed and patterned on the seed layer. The photoresist may be formed by spin coating or the like and may be exposed to light for patterning. The pattern of the photoresist corresponds to the through vias 106. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the through vias 106.

The interconnection dies 110 are singulated and placed on the release layer 104 laterally adjacent to the through vias 106. After singulation, the interconnection dies 110 may be placed on the release layer 104 using, e.g., a pick-and-place tool. The interconnection dies 110 will be utilized for direct communication between integrated circuit devices (subsequently described) of the integrated circuit package 200. In some embodiments, the interconnection dies 110 are attached after formation of the through vias 106, however, these steps may be performed in the opposite order. In the illustrated cross-section, two interconnection dies 110 are attached in the package region 100P. It should be appreciated that any desired quantity of interconnection dies 110 may be attached in each package region 100P.

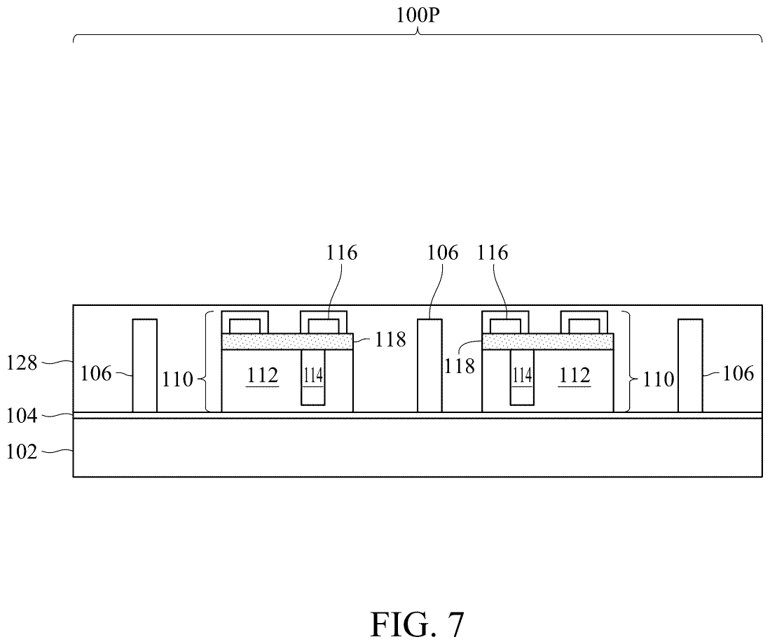

In FIG. 7, an encapsulant 128 is formed around the various components. After formation, the encapsulant 128 laterally encapsulates the interconnection dies 110 and the through vias 106. The encapsulant 128 may be a molding compound, epoxy, or the like. The encapsulant 128 may be applied by compression molding, transfer molding, or the like, and may be formed over the carrier substrate 102 such that the interconnection dies 110 and/or the through vias 106 are buried or covered. For example, portions of the encapsulant 128 may be disposed over top surfaces of the through vias 106 and the protective coverings 122. The encapsulant 128 may be formed in gap regions between the various components. The encapsulant 128 may be applied in liquid or semi-liquid form and then subsequently cured. It should be noted that the protective coverings 122 continue to protect the die connectors 116 of the interconnection dies 110 during application of the encapsulant 128. As illustrated, a die connector 116, a protective covering 122, and the encapsulant 128 collectively form a sandwich structure.

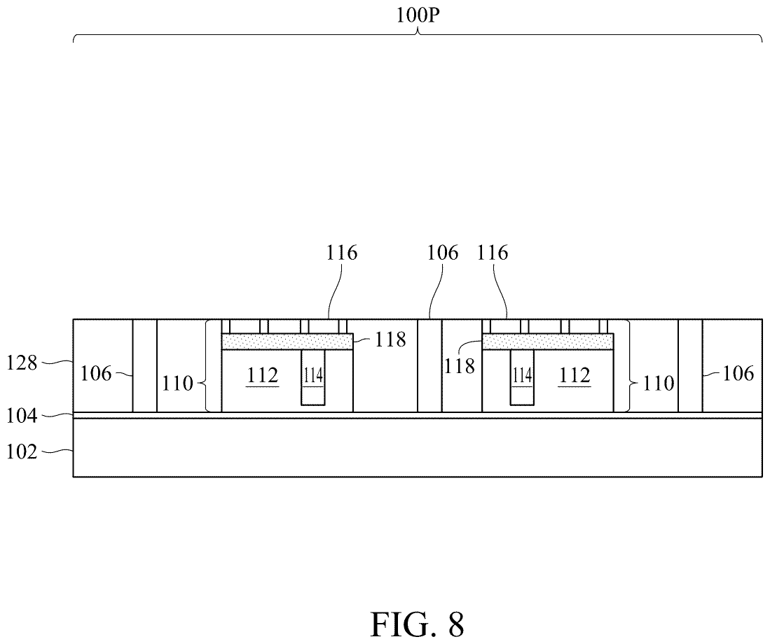

In FIG. 8, a removal process may optionally be performed on the encapsulant 128 to expose the interconnection dies 110 and the through vias 106. The removal process may remove material of the encapsulant 128, the protective coverings 122 of the interconnection dies 110, and/or the through vias 106 until the die connectors 116 and the through vias 106 are exposed. The removal process may include, for example, a planarization process such as a chemical-mechanical polish (CMP), a grinding process, the like, or a combination thereof. Front-side surfaces of the encapsulant 128, the interconnection dies 110 (e.g., the die connectors 116 and the protective coverings 122), and the through vias 106 may be substantially coplanar (within process variations) after the planarization process. The planarization may be omitted, for example, if the through vias 106 and the die connectors 116 are already exposed. After the removal process, the through vias 106 extend through the encapsulant 128. As such, the through vias 106 may be referred to as through-mold vias (TMVs).

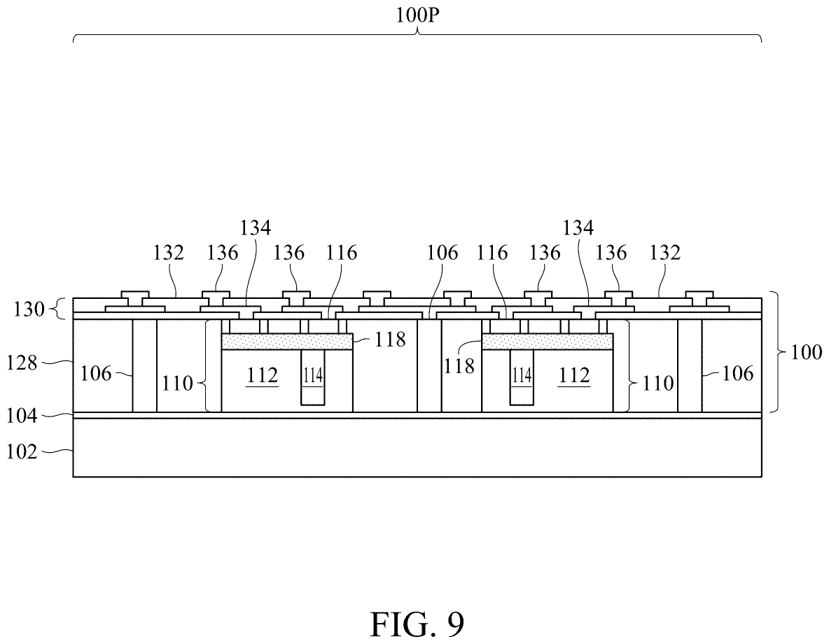

In FIG. 9, a front-side redistribution structure 130 is formed on the front-side surfaces of the encapsulant 128, the interconnection dies 110 (e.g., the die connectors 116 and the protective coverings 122), and the through vias 106. The front-side redistribution structure 130 includes dielectric layers 132 and metallization layer(s) 134 (sometimes referred to as redistribution layers or redistribution lines) among the dielectric layers 132. Thus, the front-side redistribution structure 130 includes metallization layer(s) 134 electrically connected to each other through respective dielectric layers 132. The metallization layer(s) 134 of the front-side redistribution structure 130 are electrically connected to the through vias 106 and to the interconnection dies 110 (e.g., the die connectors 116).

In some embodiments, the dielectric layers 132 are formed of a polymer, which may be a photosensitive material such as PBO, polyimide, a BCB-based polymer, or the like, that may be patterned using a lithography mask. In other embodiments, the dielectric layers 132 are formed of a nitride such as silicon nitride, an oxide such as silicon oxide, or the like. The dielectric layers 132 may be formed by spin coating, lamination, CVD, the like, or a combination thereof. After a dielectric layer 132 is formed, it may be patterned to expose underlying conductive features, such as portions of the through vias 106, the die connectors 116, and/or the metallization layer(s) 134. The patterning may be by any acceptable process, such as by exposing the dielectric layers 132 to light when they are formed of photosensitive material, or by etching using, for example, an anisotropic etch. If the dielectric layers 132 are formed of a photosensitive material, the dielectric layers 132 may be developed after the exposure.

The metallization layer(s) 134 each include conductive vias and/or conductive lines. The conductive vias extend through respective dielectric layers 132, and the conductive lines extend along respective dielectric layers 132. As an example to form a metallization layer 134, a seed layer (not separately illustrated) is formed over the respective underlying features. For example, the seed layer may be formed on a respective dielectric layer 132 and in any openings through the respective dielectric layer 132. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 134. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 134 of the front-side redistribution structure 130.

The front-side redistribution structure 130 is illustrated as an example. More or fewer dielectric layers 132 and metallization layer(s) 134 than illustrated may be formed by performing the previously described steps any desired quantity of times.

Other variations of the front-side redistribution structure 130 are contemplated. For example, some of the dielectric layers 132 may be formed of an encapsulant, such as a molding compound, epoxy, or the like. A metallization layer 134 may be formed by plating a conductive via from a conductive line. A dielectric layer 132 may be formed by encapsulating that metallization layer 134. Any desired stack of materials may be used for the dielectric layers 132.

Under-bump metallizations (UBMs) 136 may be formed through the upper dielectric layer 132 of the front-side redistribution structure 130. The UBMs 136 are physically and electrically coupled to the upper metallization layer 134 of the front-side redistribution structure 130. The UBMs 136 each include conductive vias and conductive bumps. The conductive vias extend through the upper dielectric layer 132, and the conductive bumps extend along the upper dielectric layer 132. The UBMs 136 may be formed of the same material(s) as the metallization layer(s) 134. In some embodiments, the UBMs 136 have a different size than the metallization layer(s) 134.

In FIG. 10, integrated circuit devices 202 are attached to the front-side redistribution structure 130 (e.g., the UBMs 136). Multiple integrated circuit devices 202 are placed adjacent one another in the package region 100P. The integrated circuit devices 202 in each package region 100P may include logic devices 202A and memory devices 202B. Although the illustrated cross-section shows a single logic device 202A, it should be appreciated that multiple logic devices 202A may be attached. The logic devices 202A and the memory devices 202B may be formed in processes of a same technology node, or may be formed in processes of different technology nodes. For example, the logic devices 202A may be formed by a more advanced process node than the memory devices 202B.

Each logic device 202A may be a central processing unit (CPU), graphics processing unit (GPU), system-on-a-chip (SoC), microcontroller, or the like. The logic devices 202A may be integrated circuit dies (similar to the integrated circuit die 50 described for FIG. 1) or may be die stacks (similar to the die stack 60A described for FIG. 2A). In some embodiments, the logic devices 202A are integrated circuit dies such as system-on-a-chip (SoC) dies. In some embodiments, the logic devices 202A are die stacks such as system-on-integrated-chip (SoIC) devices.

Each memory device 202B may be a dynamic random access memory (DRAM) die, static random access memory (SRAM) die, hybrid memory cube (HMC) module, a high bandwidth memory (HBM) module, or the like. The memory devices 202B may be integrated circuit dies (similar to the integrated circuit die 50 described for FIG. 1) or may be die stacks (similar to the die stack 60B described for FIG. 2B). In some embodiments, the memory devices 202B are die stacks, such as high bandwidth memory (HBM) devices.

In the illustrated embodiment, the integrated circuit devices 202 are attached to the front-side redistribution structure 130 with solder bonds, such as with conductive connectors 204. The conductive connectors 204 may be formed of a conductive material that is reflowable, such as solder, copper, aluminum, gold, nickel, silver, palladium, tin, the like, or a combination thereof. In some embodiments, the conductive connectors 204 are formed by initially forming a layer of solder through methods such as evaporation, electroplating, printing, solder transfer, ball placement, or the like. Once a layer of solder has been formed on the structure, a reflow may be performed in order to shape the conductive connectors 204 into desired bump shapes. Attaching the integrated circuit devices 202 to the front-side redistribution structure 130 may include placing the integrated circuit devices 202 on the front-side redistribution structure 130 and reflowing the conductive connectors 204. The integrated circuit devices 202 may be placed on the front-side redistribution structure 130 using, e.g., a pick-and-place tool. The conductive connectors 204 are reflowed to attach die connectors 206 at the front-sides of the integrated circuit devices 202 to the UBMs 136 of the front-side redistribution structure 130, thereby electrically connecting the front-side redistribution structure 130 to the integrated circuit devices 202. As such, the front-side redistribution structure 130 and the interconnection die 110 electrically couple the integrated circuit devices 202 to one another (e.g., electrically coupling the memory device 202B to the logic device 202A). In another embodiment, the integrated circuit devices 202 are attached to the front-side redistribution structure 130 with direct bonds, using the die connectors 206.

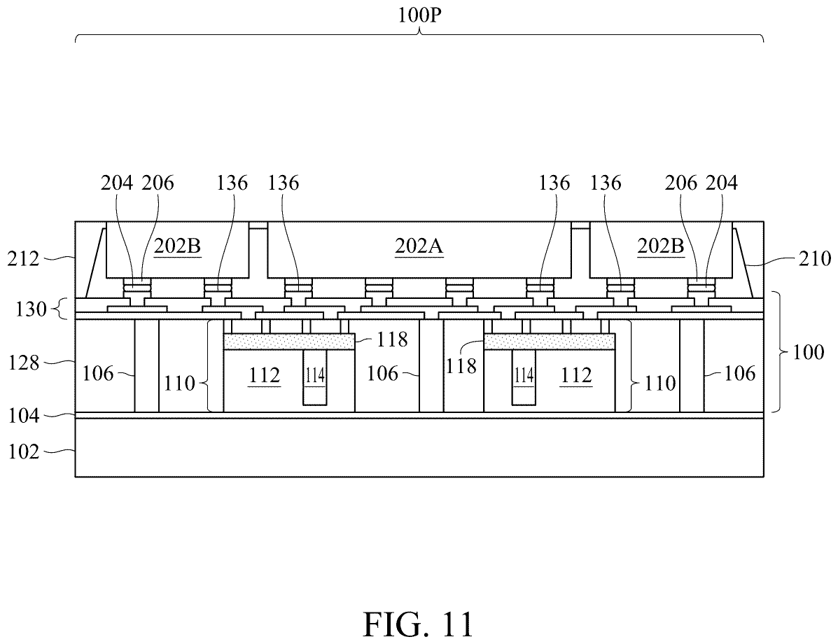

In FIG. 11, an underfill 210 may be formed around the conductive connectors 204, and between the front-side redistribution structure 130 and the integrated circuit devices 202. The underfill 210 may reduce stress and protect the joints resulting from the reflowing of the conductive connectors 204. The underfill 210 may be formed of an underfill material such as a molding compound, epoxy, or the like. The underfill 210 may be formed by a capillary flow process after the integrated circuit devices 202 are attached to the front-side redistribution structure 130, or may be formed by a suitable deposition method before the integrated circuit devices 202 are attached to the front-side redistribution structure 130. The underfill 210 may be applied in liquid or semi-liquid form and then subsequently cured.

An encapsulant 212 is formed around the various components. After formation, the encapsulant 212 laterally encapsulates the underfill 210 (if present) and the integrated circuit devices 202. The encapsulant 212 may be a molding compound, epoxy, or the like. The encapsulant 212 may be applied by compression molding, transfer molding, or the like, and may be formed over the front-side redistribution structure 130 such that the integrated circuit devices 202 are buried or covered. The encapsulant 212 is further formed in gap regions between the underfill 210 (if present) and/or the integrated circuit devices 202. The encapsulant 212 may be applied in liquid or semi-liquid form and then subsequently cured.

A removal process may optionally be performed on the encapsulant 212 to expose the integrated circuit devices 202. The removal process may include, for example, a planarization process such as a chemical-mechanical polish (CMP), a grinding process, or the like. The top surfaces of the encapsulant 212 and the integrated circuit devices 202 may be substantially coplanar (within process variations) after the planarization process. The planarization may be omitted, for example, if the integrated circuit devices 202 are already exposed.

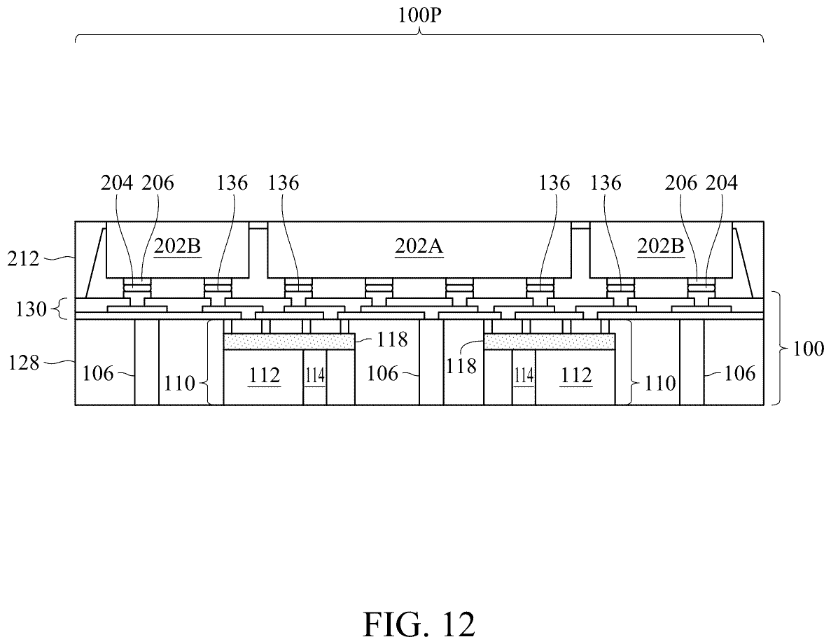

In FIG. 12, a carrier substrate de-bonding is performed to detach (or “de-bond”) the carrier substrate 102 from a back-side surface of the interposer wafer 100. In accordance with some embodiments, the de-bonding includes projecting a light such as a laser light or an UV light on the release layer 104 so that the release layer 104 decomposes under the heat of the light and the carrier substrate 102 can be removed. The interposer wafer 100 is then flipped over to prepare for processing of the back-side of the interposer wafer 100. The interposer wafer 100 may be placed on a tape, a carrier substrate, or another suitable support structure (not separately illustrated) for subsequent processing.

A removal process may then be performed on the substrates 112 and the encapsulant 128 to expose or reveal the through vias 106 and the TSVs 114. The removal process may remove material of the encapsulant 128, the interconnection dies 110 (e.g., the substrates 112 and the TSVs 114), and/or the through vias 106 until the TSVs 114 and the through vias 106 are exposed. The removal process may include, for example, a planarization process such as a chemical-mechanical polish (CMP), a grinding process, or the like. The back-side surfaces of the encapsulant 128, the interconnection dies 110 (e.g., the substrates 112 and the TSVs 114), and the through vias 106 may be substantially coplanar (within process variations) after the planarization process.

Some advantages of forming the protective coverings 122 (see FIGS. 4A-5C) are realized during the removal process. As discussed above, the protective coverings 122 are formed with particular dimensions to reduce stress in the interconnection dies 122 as well as warpage thereof. By preventing or reducing such warpage, the removal process may be performed more efficiently to expose the TSVs 114. Moreover, the removal process may also be performed with greater yield because substantially all of the TSVs 114 will be exposed by the removal process (e.g., within prescribed process parameters, such as duration, rotation speeds, and abrasiveness). As such, certain defects are prevented, such as the TSV blind defect, which otherwise occurs when some of the TSVs 114 are not exposed (e.g., remain covered by the substrate 112) after performing the removal process.

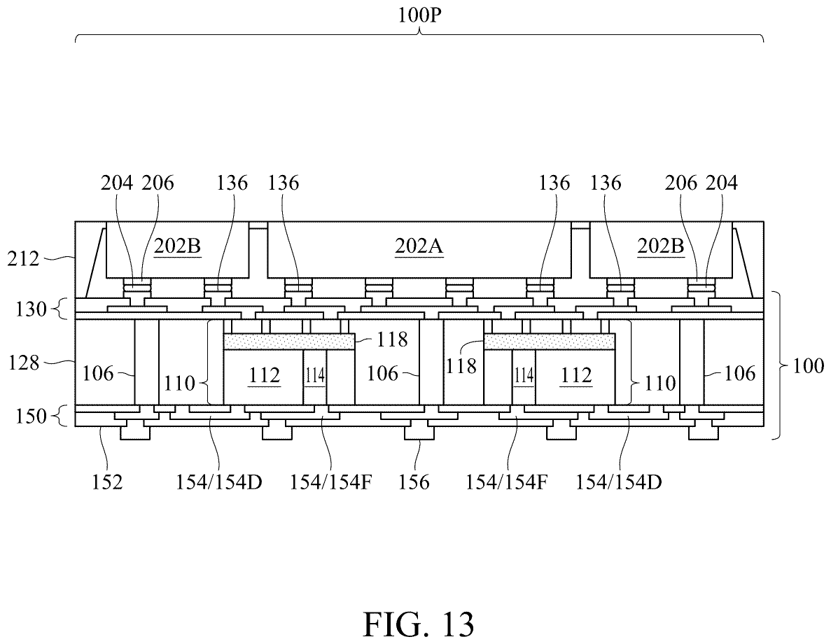

In FIG. 13, a back-side redistribution structure 150 is formed on the back-side surfaces of the encapsulant 128, the interconnection dies 110 (e.g., the substrates 112 and the TSVs 114), and the through vias 106. The back-side redistribution structure 150 includes dielectric layers 152 and metallization layer(s) 154 (sometimes referred to as redistribution layers or redistribution lines) among the dielectric layers 152. Thus, the back-side redistribution structure 150 includes metallization layer(s) 154 electrically connected to one other through respective dielectric layers 152. The metallization layer(s) 154 of the back-side redistribution structure 150 are electrically connected to the through vias 106 and to the interconnection dies 110 (e.g., the TSVs 114). As such, the back-side redistribution structure 150 is electrically connected to the front-side redistribution structure 130 through the interposer wafer 100 (e.g., the through vias 106 and the interconnection dies 110).

In some embodiments, the dielectric layers 152 are formed of a polymer, which may be a photosensitive material such as PBO, polyimide, a BCB-based polymer, or the like, that may be patterned using a lithography mask. In other embodiments, the dielectric layers 152 are formed of a nitride such as silicon nitride, an oxide such as silicon oxide, or the like. The dielectric layers 152 may be formed by spin coating, lamination, CVD, the like, or a combination thereof. After a dielectric layer 152 is formed, it may be patterned to expose underlying conductive features, such as portions of the through vias 106, the TSVs 114, and/or the metallization layer(s) 154. The patterning may be by any acceptable process, such as by exposing the dielectrics layers to light when they are formed of photosensitive material, or by etching using, for example, an anisotropic etch. If the dielectric layers 152 are formed of a photosensitive material, the dielectric layers 152 may be developed after the exposure.

The metallization layer(s) 154 each include conductive vias and/or conductive lines. The conductive vias extend through respective dielectric layers 152, and the conductive lines extend along respective dielectric layers 152. As an example to form a metallization layer 154, a seed layer (not separately illustrated) is formed over the respective underlying features. For example, the seed layer may be formed on a respective dielectric layer 152 and in any openings through the respective dielectric layer 152. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 154. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 154 of the back-side redistribution structure 150.

The back-side redistribution structure 150 is illustrated as an example. More or fewer dielectric layers 152 and metallization layer(s) 154 than illustrated may be formed by performing the previously described steps any desired quantity of times.

Other variations of the back-side redistribution structure 150 are contemplated. For example, some of the dielectric layers 152 may be formed of an encapsulant, such as a molding compound, epoxy, or the like. A metallization layer 154 may be formed by plating a conductive via from a conductive line. A dielectric layer 152 may be formed by encapsulating such a metallization layer 154. Any desired stack of materials may be used for the dielectric layers 152.

UBMs 156 may be formed through the lower dielectric layer 152 of the back-side redistribution structure 150. The UBMs 156 are physically and electrically coupled to the lower metallization layer 154 of the back-side redistribution structure 150. The UBMs 156 each include conductive vias and conductive bumps. The conductive vias extend through the lower dielectric layer 152, and the conductive bumps extend along the lower dielectric layer 152. The UBMs 156 may be formed of the same material(s) as the metallization layer(s) 154. In some embodiments, the UBMs 156 have a different size than the metallization layer(s) 154.

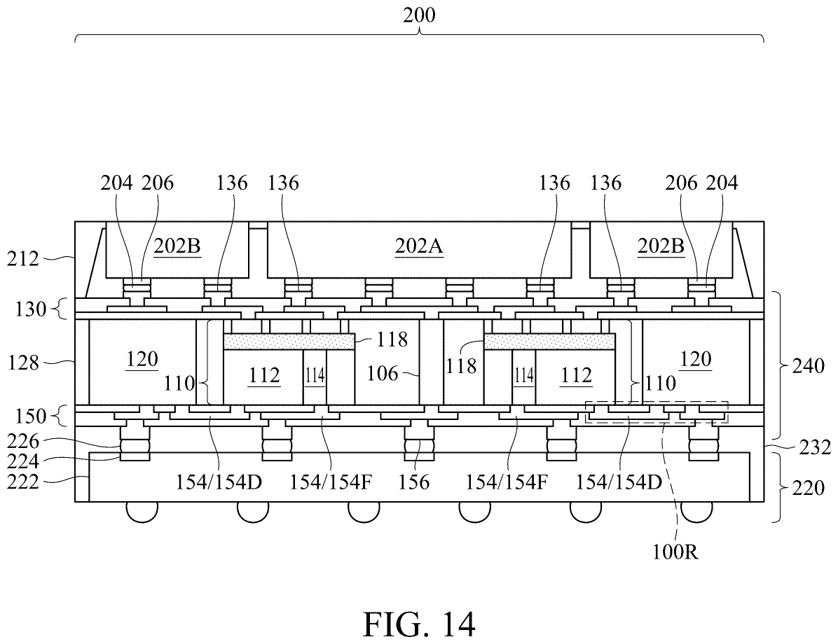

In FIG. 14, a package substrate 220 is attached to the interposer wafer 100 (e.g., to the back-side redistribution structure 150). The package substrate 220 includes a substrate core 222, which may be formed of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 222 may be a SOI substrate. Generally, an SOI substrate includes a layer of a semiconductor material such as a layer of silicon, germanium, silicon germanium, or combinations thereof. In some embodiments, the substrate core 222 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate core 222.

The substrate core 222 may include passive devices and/or active devices (not separately illustrated). Devices such as transistors, capacitors, resistors, combinations thereof, and the like may be used to generate the structural and functional requirements of the design for the system. The devices may be formed using any suitable methods. In some embodiments, the substrate core 222 is substantially free of active devices and passive devices.

The substrate core 222 may also include metallization layers (not separately illustrated). The package substrate 220 further includes bond pads 224 over the metallization layers of the substrate core 222. The metallization layers may be formed over the passive devices and/or active devices and are designed to connect the various devices to form functional circuitry. The metallization layers may be formed of alternating layers of dielectric material (e.g., low-k dielectric material) and conductive material (e.g., copper), with vias interconnecting the layers of conductive material, and may be formed through any suitable process (such as deposition, damascene, or the like).

The package substrate 220 may be attached to the back-side redistribution structure 150 with solder bonds, such as with conductive connectors 226. The conductive connectors 226 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 226 may include a conductive material such as solder, copper, aluminum, gold, nickel, silver, palladium, tin, the like, or a combination thereof. In some embodiments, the conductive connectors 226 are formed by initially forming a layer of solder through evaporation, electroplating, printing, solder transfer, ball placement, or the like. Once a layer of solder has been formed on the structure, a reflow may be performed in order to shape the solder into the desired bump shapes of the conductive connectors 226. Attaching the package substrate 220 to the back-side redistribution structure 150 may include placing the package substrate 220 on the and back-side redistribution structure 150 reflowing the conductive connectors 226. The package substrate 220 may be placed on the back-side redistribution structure 150 using, e.g., a pick-and-place tool. The conductive connectors 226 are reflowed to attach the bond pads 224 to the UBMs 156 of the back-side redistribution structure 150. The conductive connectors 226 connect the interposer wafer 100, including metallization layers of the back-side redistribution structure 150, to the package substrate 220, including metallization layers of the substrate core 222. Thus, the package substrate 220 are electrically connected to the integrated circuit devices 202 in the package region 100P.

Additionally, passive devices (not separately illustrated) may be attached to the interposer wafer 100 and/or the package substrate 220. For example, the passive devices may be attached to the interposer wafer 100, such as to the same surface of the back-side redistribution structure 150 as the conductive connectors 226. Additionally or alternatively, the passive devices may be attached to the package substrate 220, such as to the same surface of the package substrate 220 as the conductive connectors 226. The passive devices may include capacitors, resistors, inductors, the like, or a combination thereof. The passive devices may be surface mount devices (SMDs), 2-terminal integrated passive devices (IPDs), multi-terminal IPDs, or the like.

In some embodiments, an encapsulant 232 is formed around the various components. After formation, the encapsulant 232 laterally encapsulates the passive devices (if present), the conductive connectors 226, and the package substrate 220. The encapsulant 232 may be formed between the package substrate 220 and the back-side redistribution structure 150. The encapsulant 232 may be a molding compound, epoxy, or the like. The encapsulant 232 may be applied by compression molding, transfer molding, or the like. The encapsulant 232 may be applied in liquid or semi-liquid form and then subsequently cured.

Additionally, a singulation process may be performed by cutting along scribe line regions between the package region 100P and adjacent package regions (not separately illustrated). The singulation process may include sawing, dicing, or the like. The singulation process singulates the package regions from one another. The resulting, singulated integrated circuit package 200 is from the package region 100P. The singulation process forms an interposer 240 from the singulated portion of the interposer wafer 100. As a result of the singulation process, the outer sidewalls of the interposer 240, the encapsulant 212, and the encapsulant 232 are laterally coterminous (within process variations).

FIGS. 15A-15C are plan views (e.g., top-down cross-sectional views) of exemplary layouts of an interconnection die 110 within the interposer 100/240, in accordance with various embodiments. Note that the illustrated interconnection dies 110 may represent entire plan views or portions of plan views depending on the features being emphasized and described. For example, the illustrated die connectors 116 may be more numerous or have varying layouts depending on the features being emphasized and described.

In the illustrated embodiments, first protective coverings 122A may have thicknesses T_{A} around the sidewalls of first die connectors 116A, similarly as described above (see FIGS. 5A-5C). In addition, second protective coverings 122B may have thicknesses T_{B} around the sidewalls of second die connectors 116B, wherein the thickness T_{B} is greater than the thickness T_{A}. In accordance with various embodiments, both the thickness T_{A} and the thickness T_{B} may fall within the dimensions described above in connection with the thickness T₁.

Forming the protective coverings 122 with varying thicknesses may achieve various advantages. For example, shrinkage of the protective coverings 122 during curing (see FIGS. 5A-5C) may be exacerbated by subsequent steps, such as singulation of the interconnection dies 110 (see FIG. 6), compression and grinding of the encapsulant 128 (see FIGS. 7 and 8), removal of the carrier substrate 102 (see FIG. 12), and the TSV reveal process (see FIG. 12). Particular regions of the interconnection die 110 may be more susceptible to warpage due to things such as proximity to corners, dimensions of the corresponding die connectors 116, or pattern density of the corresponding die connectors 116.

Referring to FIG. 15A, the first die connectors 116A may be located proximal to corners of the interconnection die 110. In such embodiments, the corners of the interconnection die 110 may be especially susceptible to warpage. As such, the first die connectors 116A may have first protective coverings 122A with the lesser thickness T_{A} in order to prevent or reduce such warpage near the corners of the interconnection die 110. In addition, the second die connectors 116B may have second protective coverings 122B with the greater thickness T_{B} for greater insulation and structural support because the second die connectors 116B may be located in regions of the interconnection die 110 that are less susceptible to warpage (e.g., proximal to central regions and/or distal from the corners).

Referring to FIG. 15B, the first die connectors 116A may be located proximal to corners and edges of the interconnection die 110. In such embodiments, the corners and edges of the interconnection die 110 may be especially susceptible to warpage. As such, the first die connectors 116A may have first protective coverings 122A with the lesser thickness T_{A} in order to prevent or reduce such warpage near the corners and edges of the interconnection die 110. In addition, the second die connectors 116B may have second protective coverings 122B with the greater thickness T_{B} for greater insulation and structural support.

Referring to FIG. 15C, the first die connectors 116A may be located proximal to central regions of the interconnection die 110, and the second die connectors 116B may be located proximal to perimeter regions of the interconnection die 110. In such embodiments, the central region of the interconnection die 110 may be especially susceptible to warpage. As such, the first die connectors 116A may have first protective coverings 122A with the lesser thickness T_{A} in order to prevent or reduce such warpage of the interconnection die 110. In addition, the second die connectors 116B may have second protective coverings 122B with the greater thickness T_{B} for greater insulation and structural support.

Referring still to FIGS. 15A-15C, the first die connectors 116A may have diameters D_{A} while the second die connectors 116B have diameters D_{B}. The diameters D_{A} and D_{B} may be substantially the same, or the diameter D_{B} may be greater than or less than the diameter D_{A}. In some embodiments, the relative thicknesses T_{A} and T_{B} of the protective coverings 122A and 122B, respectively, may be based on the relative diameters D_{A} and D_{B} of the die connectors 116A and 116B, respectively. For example, the die connectors 116 with greater diameters may have protective coverings 122 with greater thicknesses, and vice versa. In accordance with various embodiments, both the diameter D_{A} and the diameter D_{B} may fall within the dimensions described above in connection with the lateral diameter D₁.

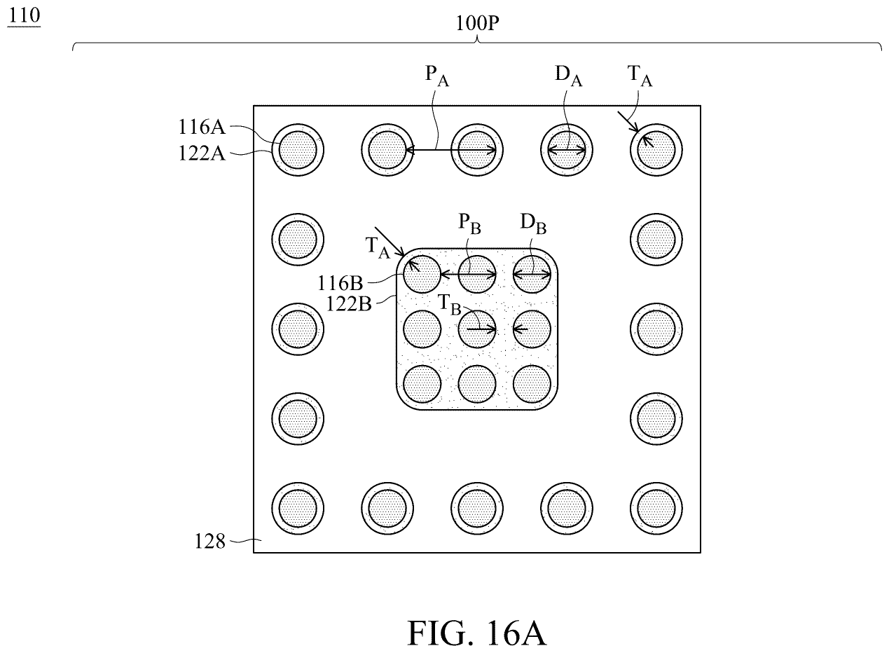

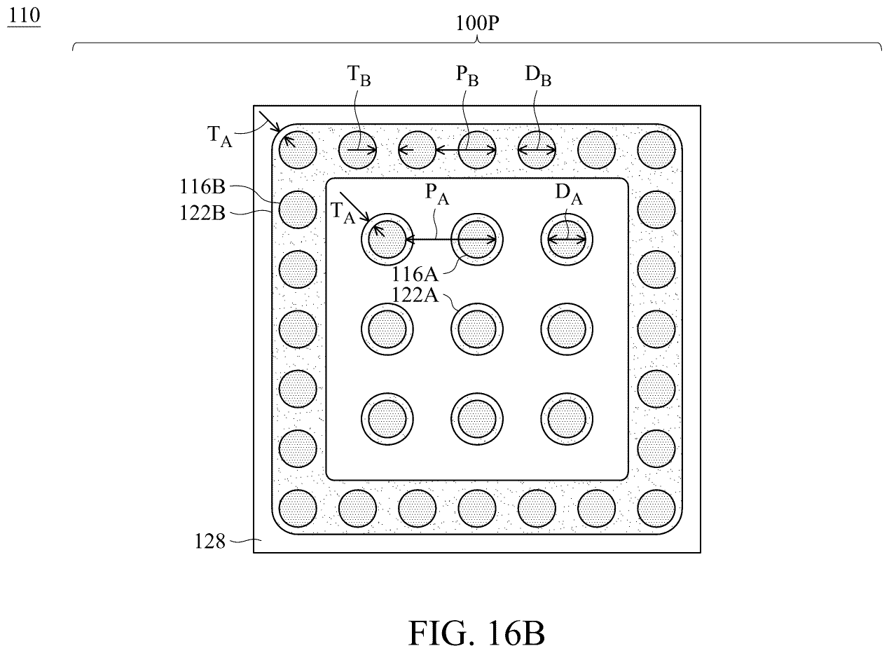

FIGS. 16A and 16B are plan views (e.g., top-down cross-sectional views) of exemplary layouts of an interconnection die 110 within the interposer 100/240, in accordance with various embodiments. Note that the illustrated interconnection dies 110 may represent entire plan views or portions of plan views depending on the features being emphasized and described. For example, the illustrated die connectors 116 may be more numerous or have varying layouts depending on the features being emphasized and described. In the illustrated embodiments, first protective coverings 122A may have thicknesses T_{A} around the sidewalls of corresponding first die connectors 116A (e.g., in a one-to-one correspondence), similarly as described above (see FIGS. 5A-5C). In addition, a single second protective covering 122B may surround the sidewalls of a plurality of second die connectors 116B. The second protective covering 122B may have the thickness T_{A} in some portions as well as greater thicknesses T_{B} elsewhere (e.g., between adjacent second die connectors 116B). In accordance with various embodiments, the thicknesses T_{A} and T_{B} may fall within the dimensions described above in connection with the thickness T₁.

Forming the first protective coverings in a one-to-one correspondence with the first die connectors 116A and the second protective covering(s) 122B covering a plurality of the second die connectors 116B may achieve various advantages. For example, shrinkage of the protective coverings 122 during curing (see FIGS. 5A-5C) may be exacerbated by subsequent steps, such as singulation of the interconnection dies 110 (see FIG. 6), compression and grinding of the encapsulant 128 (see FIGS. 7 and 8), removal of the carrier substrate 102 (see FIG. 12), and the TSV reveal process (see FIG. 12). As such, the first protective coverings 122A may achieve similar benefits as described above in connection with previous embodiments. In addition, the second die connectors 116B may be arranged in a greater pattern density such that having individual protective coverings 122B would be less feasible. As such, the single protective covering 122B surrounding the plurality of the second die connectors 116B prevents the effects of thermal coefficient mismatches between the protective coverings 122B and intervening portions of the encapsulant 128 (e.g., preventing such warpage and delamination).

Note that variations in the pattern densities between the first die connectors 116A and the second die connectors 116B may be attributable to one or more of several factors. For example, diameters D_{A} of the first die connectors 116A may be lesser than diameters D_{B} of the second die connectors 116B. In addition, a pitch P_{A} of the first die connectors 116A may be greater than a pitch P_{B} of the second die connectors 116B. Further, geometric layouts may vary such that, for example, some of the die connectors 116 may be arranged in a less dense layout (e.g., square packing, as illustrated) while others of the die connectors 116 may be arranged in a denser layout (e.g., triangular or hexagonal packing). Note that any combinations of these factors may contribute to varying pattern densities among the die connectors 116.

Referring to FIG. 16A, the first die connectors 116A may be located proximal to perimeter regions of the interconnection die 110, and the second die connectors 116B may be located proximal to central regions of the interconnection die 110. In such embodiments, the second die connectors 116B may be arranged in a greater pattern density than the first die connectors 116A. As a result, each of the first protective coverings 122A surrounds a single one of the first die connectors 116A, while the second protective covering 122B has a merged structure to surround a plurality of the second die connectors 116B which have a smaller pitch P_{B} and/or a greater diameter D_{B} as compared to the first die connectors 116A. Note that a plurality of the second protective coverings 122B may each surround different clusters or groupings of the second die connectors 116B.

Referring to FIG. 16B, the first die connectors 116A may be located proximal to central regions of the interconnection die 110, and the second die connectors 116B may be located proximal to perimeter regions of the interconnection die 110. In such embodiments, the second die connectors 116B may be arranged in a greater pattern density than the first die connectors 116A. As a result, each of the first protective coverings 116A surrounds a single one of the first die connectors 116A, while the second protective covering 122B has a merged structure to surround a plurality of the second die connectors 116B which have a smaller pitch P_{B} and/or a greater diameter D_{A} as compared to the first die connectors 116A. As illustrated, the second protective covering 122B may form a continuous ring that encircles some or all of the first die connectors 116A and the first protective coverings 122A. Note that a plurality of the second protective coverings 122B may each surround different clusters or groupings of the second die connectors 116B. For example, the second protective coverings 122B may form a discontinuous ring that encircles some or all of the first die connectors 116A and the first protective coverings 122A.

Referring still to FIGS. 16A and 16B, the first die connectors 116A may have diameters D_{A} while the second die connectors 116B have smallest diameters D_{B}. The diameters D_{A} and D_{B} may be substantially the same, or the diameter D_{B} may be greater than or less than the diameter D_{A}. In some embodiments, the relative thicknesses T_{A} and T_{B} of the protective coverings 122A and 122B, respectively, may be based on the relative diameters D_{A} and D_{B} of the die connectors 116A and 116B, respectively. For example, the die connectors 116 with greater diameters may have protective coverings 122 with greater thicknesses, and vice versa. In accordance with various embodiments, both the diameter D_{A} and the diameter D_{B} may fall within the dimensions described above in connection with the lateral diameter D₁.

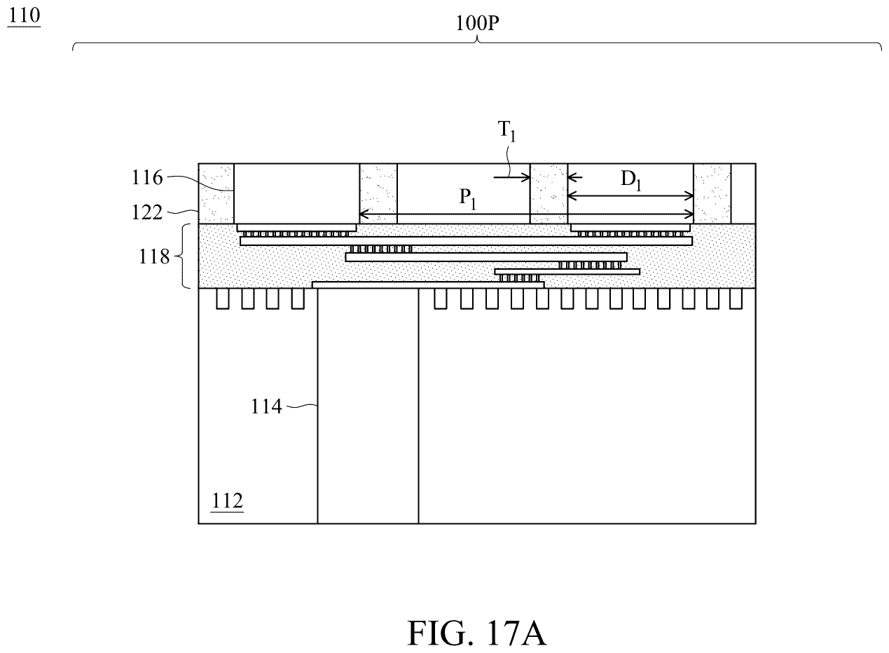

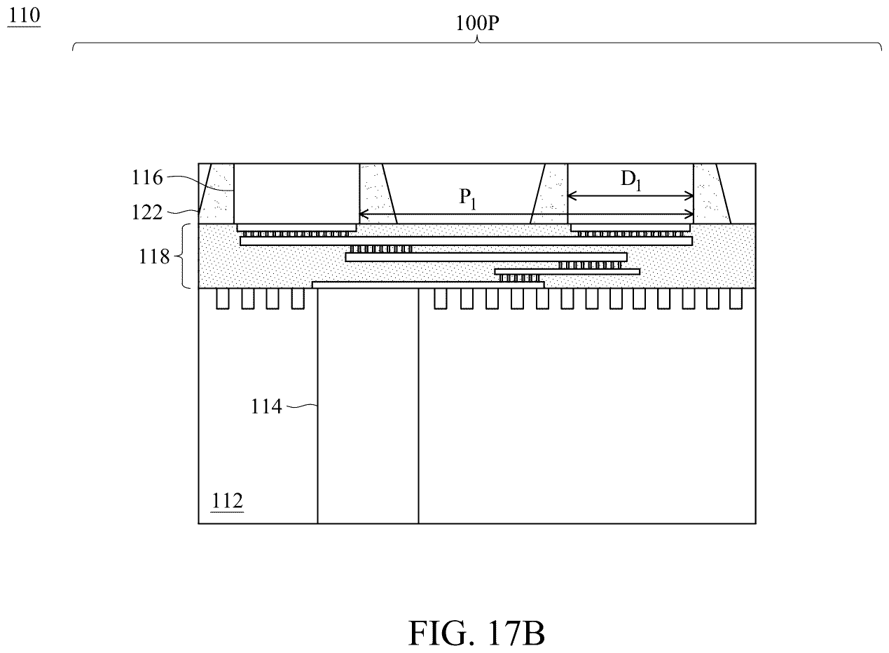

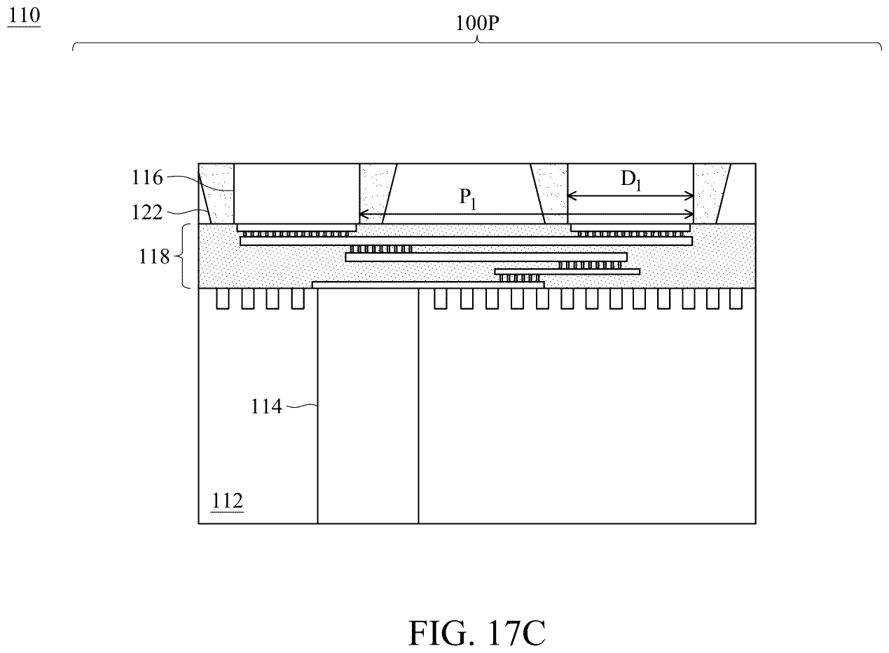

FIGS. 17A-17C are close-up cross-sectional side views of exemplary interconnection dies 110 within the interposer 100/240, in accordance with various embodiments. Various profile shapes of the protective coverings 122 are illustrated, which may provide various benefits as described in greater detail below.

Referring to FIG. 17A, the protective coverings 122 may have a straight or rectangular profile shape around the die connectors 116. For example, the process of patterning the protective layer 120 into the protective coverings 122 (see FIGS. 5A-5C) may result in the protective coverings 122 having a substantially same thickness T₁ along the height of the die connectors 116 (e.g., from the die bridge 118 to the front-side redistribution structure 130). As a result, the sidewalls of the die connectors 116 receive consistent protection, insulation, and structural support.

Referring to FIG. 17B, the protective coverings 122 may have sloped sidewalls to form an upright trapezoidal profile shape (e.g., an upright right triangular shape on each side) around the die connectors 116. In particular, the process of patterning the protective layer 120 into the protective coverings 122 may be designed to achieve this profile shape. For example, a positive photolithography may be utilized to allow light to expose portions of the protective layer 120 which will be removed by the developer such that the remaining portions of the protective layer 120 become the protective coverings 122. In some embodiments, the light exposure along edges of the mask may be greater in upper portions of the protective layer 120 (e.g., proximal to the mask and distal from the die bridge 118) as compared to lower portions of the protective layer (e.g., distal from the mask and proximal to the die bridge 118). As a result, the exposed portions of the protective layer 120 may have V-shaped sidewalls, and removal of those exposed portions during development may result in the upright trapezoidal profile shape (e.g., an upright right triangular shape on each side) of the protective coverings 122. Note that the protective coverings 122 may have smallest and largest thicknesses (e.g., along the sidewall of the die connector 116) which fall within the dimensions described above in connection with the thickness T₁. As further illustrated, some of the die connectors 116 proximal to perimeter regions of the interconnection die 110 may have protective coverings 122 which extend over the scribe region. As such, those portions of the trapezoidal profile shape (e.g., the right triangular shape along the sidewall) may be cut from the singulation process.

The upright trapezoidal profile shape of the protective coverings 122 may achieve some additional benefits. In particular, the larger thicknesses of the protective coverings 122 provide added protection to portions of the interconnection die 110 which may benefit, such as some of the upper conductive features of the die bridge 118. In addition, the smaller thicknesses of the protective coverings 122 reduce the above-described thermal coefficient mismatch effects in portions of the interposer 100/240 proximal to other components to reduce risks of delamination, such as with respect to the front-side redistribution structure 130.

Referring to FIG. 17C, the protective coverings 122 may have sloped sidewalls to form an inverted trapezoidal profile shape (e.g., an inverted right triangular shape on each side) around the die connectors 116. In particular, the process of patterning the protective layer 120 into the protective coverings 122 may be designed to achieve this profile shape. For example, a negative photolithography may be utilized to allow light to expose portions of the protective layer 120 which will remain (e.g., will not be removed by the developer) and become the protective coverings 122. In some embodiments, the light exposure along edges of the mask may be greater in upper portions of the protective layer 120 (e.g., proximal to the mask and distal from the die bridge 118) as compared to lower portions of the protective layer (e.g., distal from the mask and proximal to the die bridge 118). As a result, the exposed portions of the protective layer 120 may have V-shaped sidewalls which remain after development as the inverted trapezoidal profile shape (e.g., an inverted right triangular shape on each side) of the protective coverings 122. Note that the protective coverings 122 may have smallest and largest thicknesses (e.g., along the sidewall of the die connector 116) which fall within the dimensions described above in connection with the thickness T₁. As further illustrated, some of the die connectors 116 proximal to perimeter regions of the interconnection die 110 may have protective coverings 122 which extend over the scribe region. As such, those portions of the trapezoidal profile shape (e.g., the right triangular shape along the sidewall) may be cut from the singulation process.

The inverted trapezoidal profile shape of the protective coverings 122 may achieve some additional benefits. In particular, the larger thicknesses of the protective coverings 122 provide added protection to portions of the interposer 100/240 which may benefit, such as some of the lower conductive features of the front-side redistribution structure 130. In addition, the smaller thicknesses of the protective coverings 122 reduce the above-described thermal coefficient mismatch effects in portions of the interconnection die 110 proximal to other components to reduce stress and warpage of the interconnection die 110, such as with respect to the die bridge 118 of the interconnection die 110.

Embodiments may achieve advantages. The interconnection dies 110 include the die connectors 116 which facilitate electrical connection between the interconnection dies 110 and various other components of the interposer 100/240 (and with the integrated circuit package 200 at large). As such, the protective coverings 122 are formed over and around the die connectors 116 to protect the conductive material of the die connectors 116 while providing insulation and structural benefits. In some embodiments, formation of the protective coverings 122 may include a curing process which may form stress in the interconnection die 110, and the stress may further cause warpage of the interconnection die 110. As such, the protective coverings 122 are formed with limited thicknesses that provide the above-described benefits while reducing such stress and reducing or preventing such warpage. Furthermore, the interconnection dies 110 may have flatter front-side and back-side surfaces which benefit subsequent processes, such as formation of the front-side redistribution structure 130, revealing of the TSVs 114 of the interconnection die 110, and formation of the back-side redistribution structure 150.

In an embodiment, a method includes: forming an interconnection die, the interconnection die including: through vias extending partially through a semiconductor substrate; an interconnect structure over the semiconductor substrate; and die connectors over the interconnect structure; applying a protection layer over the die connectors; patterning the protection layer to form protective coverings around the die connectors; forming an encapsulant over and around the interconnection die and the protective coverings; performing a first planarization process to level the encapsulant, the protective coverings, and the die connectors; and forming a first redistribution structure over and electrically connected to the die connectors. In some embodiments of the method, first thicknesses of a first set of the protective coverings are greater than second thicknesses of a second set of the protective coverings. In some embodiments of the method, in a top-down cross-section the first set is located proximal to a perimeter region of the interconnection die, where in the top-down cross-section the second set is located proximal to a central region of the interconnection die. In some embodiments of the method, in a top-down cross-section the first set is located proximal to a central region of the interconnection die, where in the top-down cross-section the second set is located proximal to a perimeter region of the interconnection die. In some embodiments of the method, a single protective covering of the first set of the protective coverings covers a first set of the die connectors, where the second set of the protective coverings covers a second set of the die connectors in a one-to-one correspondence. In some embodiments of the method, a first pattern density of the first set of the die connectors is greater than a second pattern density of the second set of the die connectors. In some embodiments, the method further includes: after patterning the protection layer, attaching the interconnection die to a substrate; and attaching integrated circuit dies to the first redistribution structure. In some embodiments, the method further includes: removing the substrate; performing a planarization process to expose a through substrate via of the interconnection die; and forming a second redistribution structure over and electrically connected to the through substrate via.

In an embodiment, a method includes: forming an interconnection die, forming the interconnection die including: forming a through via partially through a substrate; forming an interconnect structure over the substrate; forming a first die connector and a second die connector over the interconnect structure; and forming a first dielectric covering over the first die connector and a second dielectric covering over the second die connector; attaching the interconnection die over a carrier substrate; forming an encapsulant over and around the interconnection die; planarizing the encapsulant to expose the first die connector and the second die connector; forming a first redistribution structure over the encapsulant, the first die connector, and the second die connector; and attaching an integrated circuit die over the first redistribution structure. In some embodiments of the method, forming the first dielectric covering and the second dielectric covering includes: depositing a dielectric layer over the first die connector and the second die connector; and patterning the dielectric layer to form the first dielectric covering and the second dielectric covering. In some embodiments of the method, a first thickness of the first dielectric covering is lesser than a second thickness of the second dielectric covering. In some embodiments of the method, the first die connector is located proximal to a perimeter region of the interconnection die, where the second die connector is located proximal to a central region of the interconnection die. In some embodiments, the method further includes forming a third die connector over the interconnect structure, where the second dielectric covering is disposed along respective sidewalls of the second die connector and the third die connector. In some embodiments of the method, in a side cross-sectional view each of the first dielectric covering and the second dielectric covering includes an upright right triangular profile shape.

In an embodiment, a semiconductor device includes: a back-side redistribution structure disposed over a package substrate; an encapsulant disposed over the back-side redistribution structure; a front-side redistribution structure disposed over the encapsulant; a through molding via embedded in the encapsulant and electrically coupling the front-side redistribution structure to the back-side redistribution structure; and an interconnection die embedded in the encapsulant, the interconnection die including: a semiconductor substrate; an interconnect structure disposed over the semiconductor substrate; a first die connector disposed over the interconnect structure and electrically connected to the front-side redistribution structure; and a first dielectric covering directly interposed between the first die connector and the encapsulant, a first lateral thickness of the first dielectric covering being lesser than a first lateral diameter of the first die connector. In some embodiments of the semiconductor device, the interconnection die further includes: a second die connector disposed over the interconnect structure; and a second dielectric covering directly interposed between the second die connector and the encapsulant. In some embodiments of the semiconductor device, a second lateral thickness of the second dielectric covering being greater than the first lateral thickness of the first dielectric covering. In some embodiments of the semiconductor device, a second lateral diameter of the second die connector is equal to the first lateral diameter. In some embodiments of the semiconductor device, the first die connector is located proximal to a perimeter region of the interconnection die, where the second die connector is located proximal to a central region of the interconnection die. In some embodiments, the semiconductor device further includes: a memory device attached to the front-side redistribution structure; and a logic device attached to the front-side redistribution structure, where the front-side redistribution structure and the interconnection die electrically couple the memory device to the logic device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an interconnection die, the interconnection die comprising:
through vias extending partially through a semiconductor substrate;
an interconnect structure over the semiconductor substrate; and
die connectors over the interconnect structure;
applying a protection layer over the die connectors;
patterning the protection layer to form protective coverings around the die connectors;
forming an encapsulant over and around the interconnection die and the protective coverings;
performing a first planarization process to level the encapsulant, the protective coverings, and the die connectors; and
forming a first redistribution structure over and electrically connected to the die connectors.

2. The method of claim 1, wherein first thicknesses of a first set of the protective coverings are greater than second thicknesses of a second set of the protective coverings.

3. The method of claim 2, wherein in a top-down cross-section the first set is located proximal to a perimeter region of the interconnection die, and wherein in the top-down cross-section the second set is located proximal to a central region of the interconnection die.

4. The method of claim 2, wherein in a top-down cross-section the first set is located proximal to a central region of the interconnection die, and wherein in the top-down cross-section the second set is located proximal to a perimeter region of the interconnection die.

5. The method of claim 2, wherein a single protective covering of the first set of the protective coverings covers a first set of the die connectors, and wherein the second set of the protective coverings covers a second set of the die connectors in a one-to-one correspondence.

6. The method of claim 5, wherein a first pattern density of the first set of the die connectors is greater than a second pattern density of the second set of the die connectors.

7. The method of claim 1, further comprising:
after patterning the protection layer, attaching the interconnection die to a substrate; and
attaching integrated circuit dies to the first redistribution structure.

8. The method of claim 7, further comprising:
removing the substrate;
performing a planarization process to expose a through substrate via of the interconnection die; and
forming a second redistribution structure over and electrically connected to the through substrate via.

9. A method comprising:
forming an interconnection die, forming the interconnection die comprising:
forming a through via partially through a substrate;
forming an interconnect structure over the substrate;
forming a first die connector and a second die connector over the interconnect structure; and
forming a first dielectric covering over the first die connector and a second dielectric covering over the second die connector;
attaching the interconnection die over a carrier substrate;
forming an encapsulant over and around the interconnection die;
planarizing the encapsulant to expose the first die connector and the second die connector;
forming a first redistribution structure over the encapsulant, the first die connector, and the second die connector; and
attaching an integrated circuit die over the first redistribution structure.

10. The method of claim 9, wherein forming the first dielectric covering and the second dielectric covering comprises:
depositing a dielectric layer over the first die connector and the second die connector; and
patterning the dielectric layer to form the first dielectric covering and the second dielectric covering.

11. The method of claim 9, wherein a first thickness of the first dielectric covering is lesser than a second thickness of the second dielectric covering.

12. The method of claim 11, wherein the first die connector is located proximal to a perimeter region of the interconnection die, and wherein the second die connector is located proximal to a central region of the interconnection die.

13. The method of claim 9, further comprising forming a third die connector over the interconnect structure, wherein the second dielectric covering is disposed along respective sidewalls of the second die connector and the third die connector.

14. The method of claim 9, wherein in a side cross-sectional view each of the first dielectric covering and the second dielectric covering comprises an upright right triangular profile shape.

15. A semiconductor device comprising:
a back-side redistribution structure disposed over a package substrate;
an encapsulant disposed over the back-side redistribution structure;
a front-side redistribution structure disposed over the encapsulant;
a through molding via embedded in the encapsulant and electrically coupling the front-side redistribution structure to the back-side redistribution structure; and
an interconnection die embedded in the encapsulant, the interconnection die comprising:
a semiconductor substrate;
an interconnect structure disposed over the semiconductor substrate;
a first die connector disposed over the interconnect structure and electrically connected to the front-side redistribution structure; and
a first dielectric covering directly interposed between the first die connector and the encapsulant, a first lateral thickness of the first dielectric covering being lesser than a first lateral diameter of the first die connector.

16. The semiconductor device of claim 15, wherein the interconnection die further comprises:
a second die connector disposed over the interconnect structure; and
a second dielectric covering directly interposed between the second die connector and the encapsulant.

17. The semiconductor device of claim 16, wherein a second lateral thickness of the second dielectric covering being greater than the first lateral thickness of the first dielectric covering.

18. The semiconductor device of claim 17, wherein a second lateral diameter of the second die connector is equal to the first lateral diameter.

19. The semiconductor device of claim 18, wherein the first die connector is located proximal to a perimeter region of the interconnection die, and wherein the second die connector is located proximal to a central region of the interconnection die.

20. The semiconductor device of claim 15, further comprising:
a memory device attached to the front-side redistribution structure; and
a logic device attached to the front-side redistribution structure, wherein the front-side redistribution structure and the interconnection die electrically couple the memory device to the logic device.
